(19) United States
(12) Patent Application Publication
(10) Pub. No.: US 2004/0160740 A1
(43) Pub. Date: Aug. 19, 2004

(54) Method and system for a heat sink integrated in a wall of a computing device

(76) Inventor: Prosenjit Ghosh, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/367,446

(22) Filed: Feb. 14, 2003

(51) Int. Cl. G06F 1/20; H05K 5/00; H05K 7/20

(52) U.S. Cl. 361/687

(57) ABSTRACT

A method and system for a heat sink integrated in a wall of a computing device is described. The computing device includes a heat sink integrated in a wall of the computing device, and a heat conduit to transfer heat generated by a heat source to the heat sink. The heat sink allows ambient air external to the computing device to flow into the computing device to cool the transferred heat from the heat source.

### BACKGROUND

1. Technical Field

Embodiments of the invention relate to the field of thermal management in computing devices, and more specifically to a heat sink integrated in a wall of a computing device.

2. Background Information and Description of Related Art

Mobile computing systems, such as laptops or tablet personal computers (PCs), generally comprise a large number of electronic components housed within an enclosure that has a comparatively small form factor.

These electronic components generate significant quantities of heat during operation. Therefore, there is a need for some thermal management solution to dissipate the heat in an efficient manner so that the components may operate normally.

One existing solution is for heat dissipation in computing systems to include a heat pipe to transfer the heat from a heat source, such as a central processing unit (CPU), to a heat exchanger located at a corner of the computing device. A fan next to the heat exchanger may provide cool air for the heat exchanger, enabling the heat exchanger to take in the hot air from the heat source and provide cooler air to the computing device. However, for small computing systems, there is an increasing premium for volumetric space. There may not be enough room in the computing device for the heat exchanger and the fan.

Another solution is to have a heat sink physically mounted to a heat generating component that requires cooling. The heat sink is of a conductive material and draws heat from the heat generating component by conduction where after it radiates the heat through the cooling fins. This solution requires the heat generating component to have sufficient surface area to permit the mounting of the heat sink thereon. However, in some cases a heat generating component may lack the required surface area to permit such a mounting. This can be a problem, particularly where there is a large concentration of heat generating components that each individually lack the surface dimension to permit mounting of a heat sink thereon.

### BRIEF DESCRIPTION OF DRAWINGS

The invention may best be understood by referring to the following description and accompanying drawings that are used to illustrate embodiments of the invention. In the drawings:

FIG. 1 is a block diagram illustrating one generalized embodiment of a computing device according to the invention.

FIG. 2 is a block diagram illustrating a portion of the computing device containing the heat sink and heat conduit in greater detail according to an embodiment of the invention.

FIG. 3a and FIG. 3b are side views of the computing device according to an embodiment of the invention.

FIG. 4 is a top view of the computing device according to an embodiment of the invention.

FIG. 5 is a flow diagram illustrating a method according to an embodiment of the invention.

### DETAILED DESCRIPTION

Embodiments of a system and method for a heat sink integrated in a wall of a computing device are described. In the following description, numerous specific details are set forth. However, it is understood that embodiments of the invention may be practiced without these specific details. In other instances, well-known circuits, structures and techniques have not been shown in detail in order not to obscure the understanding of this description.

Reference throughout this specification to “one embodiment” or “an embodiment” means that a particular feature, structure, or characteristic described in connection with the embodiment is included in at least one embodiment of the invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

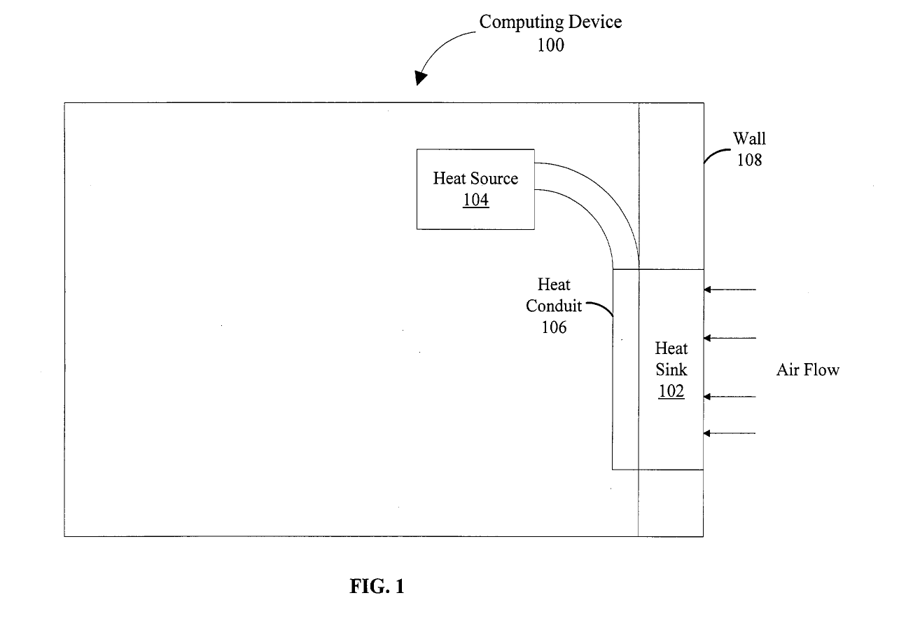

Referring to FIG. 1, a block diagram illustrates a computing device 100 according to one embodiment of the invention. Those of ordinary skill in the art will appreciate that the computing device 100 may include more components than those shown in FIG. 1. However, it is not necessary that all of these generally conventional components be shown in order to disclose an illustrative embodiment for practicing the invention.

The computing device 100 includes a heat sink 102 integrated in a wall 108 of the computing device 100. A heat conduit 106 transfers heat generated by a heat source 104 to the heat sink 102. In one embodiment, the heat conduit 106 is a pipe that couples the heat source 104 to the heat sink 102. In one embodiment, the heat conduit 106 is adjacently attached to the heat sink 102. In another embodiment, the heat conduit may be mounted on the top or bottom of the heat sink. In yet another embodiment, the heat conduit is integrated into the heat sink.

The heat source may be a central processing unit (CPU) or any other component in the computing device that generates heat, such as a memory controller. The heat sink 102 exposes the transferred heat from the heat source to ambient air external to the computing device. The heat sink 102 relies on natural air flow to draw cooler air from outside the computing device to cool the transferred heat from the heat source. Therefore, a fan is not necessary in the device. However, an air movement device, such as a fan, may be incorporated in the computing system to blow ambient air toward the heat sink.

In one embodiment, the heat sink is integrated into a side wall of the computing device. In one embodiment, more than one wall of the computing device has an integrated heat sink, and the computing device transfers heat from its internal components to the walls that have integrated heat sinks, where the heat sinks cool the transferred heat. In one embodiment, the computing device detects whether the flow of air to the heat sink is obstructed, and if so, transfers the heat from its heat sources to another unobstructed heat sink in the device.

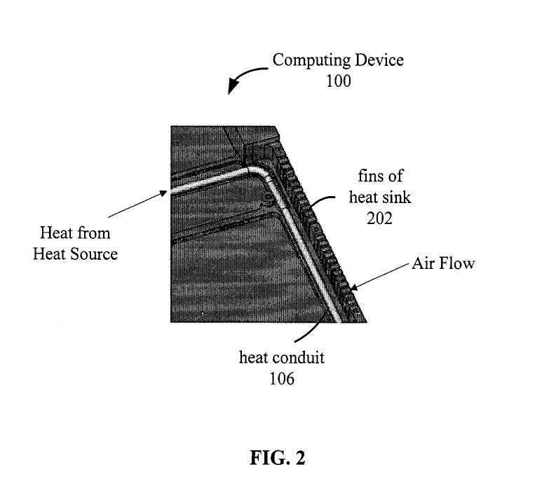

FIG. 2 is a block diagram of a portion of the computing device 100 containing the heat sink and heat conduit illustrated in greater detail according to an embodiment of the invention. As shown, heat sink 102 has a plurality of fins 202. The fins are spaced apart to allow air external to the computing device to naturally flow into the computing device. In one embodiment, the fins are perpendicular to the heat flow. The heat generated by the heat source 104 travels via the heat conduit 106 to the heat sink 102. The heat sink cools the transferred heat by exposing the heat to ambient air external to the computing device via the gaps between the fins of the heat sink. In one embodiment, the dimensions of the heat sink are 14 mm in height, 70 mm in length, and 6 mm thick. In one embodiment each fin of the heat sink is 14 mm in height, 2.5 mm in thickness, and 2 mm in depth. In one embodiment, the space between each pair of fins is 2 mm.

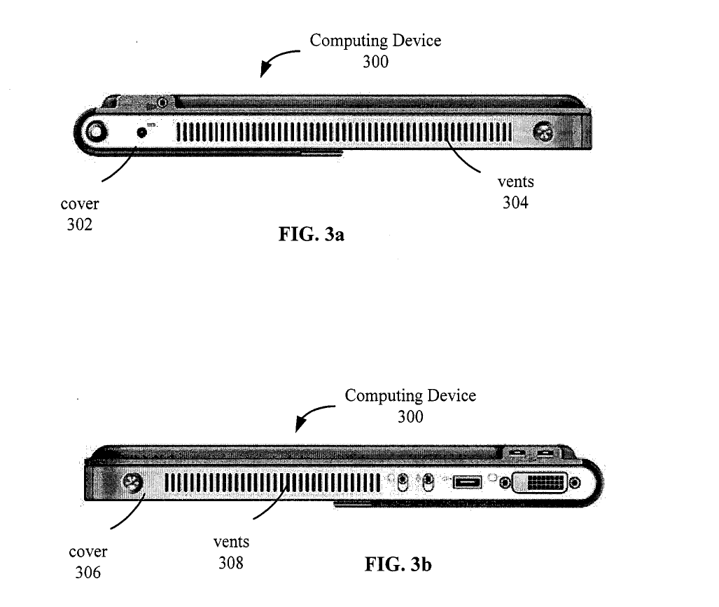

FIGS. 3a and 3b are side views of a computing device 300 according to an embodiment of the invention. The computing device includes a cover 302 or 306 to cover the wall 108 that has the integrated heat sink 102. The cover includes vents 304 or 308. The vents are aligned with the gaps between the fins of the heat sink 102 to allow air external to the computing device to travel into the computing device. The cover insulates the integrated heat sink wall and provides a cooler surface for handling by a user of the computing device. In one embodiment, the cover is made of plastic.

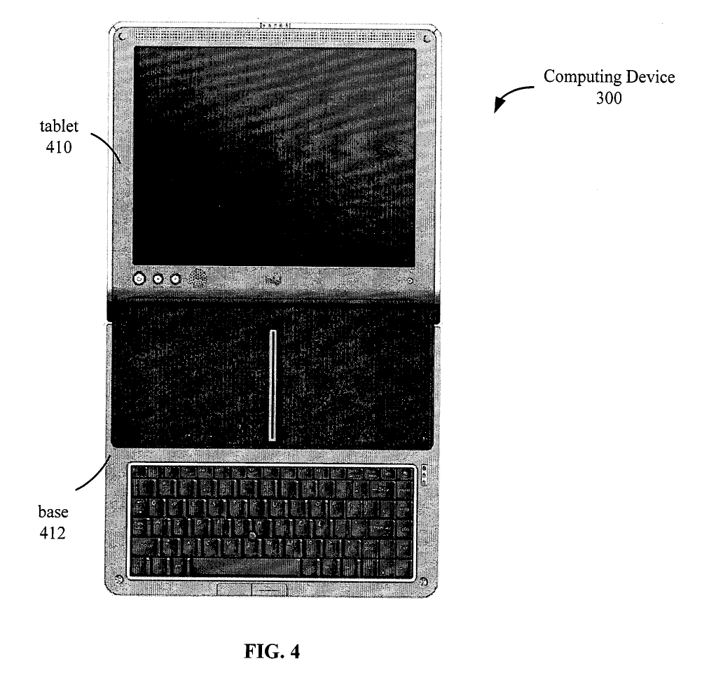

FIG. 4 is a top view of the computing device 300 according to an embodiment of the invention. In one embodiment, the computing device 300 is a mobile computing device, such as a laptop. In one embodiment, the computing device 300 is a tablet personal computer (PC) with a base 412, and a detachable tablet unit 410. The base 412 includes a keyboard, which is used to input data into the tablet unit 410 when the computing device 300 is operated in a laptop mode. The tablet unit includes a screen used for entering and displaying data. The screen is coupled with a digitizer. In a tablet mode, a user may enter handwriting directly on the screen with a tablet pen. The handwriting is digitized by the digitizer and handwriting recognition software then converts the handwriting into text. In one embodiment, the tablet unit 410 includes various computer components, such as a processor, a memory, a data storage device, and/or a network interface coupled to each other via a bus. In one embodiment, the dimensions of the computing device are 295 mm by 240 mm by 25 mm.

In one embodiment, the tablet unit 410 is housed within an enclosure which incorporates the thermal management solution of the invention. In this embodiment, the enclosure comprises a generally rectangular hollow-form body comprising a plurality of walls. In one embodiment, each of the walls are made of aluminum. At least one of the walls includes a heat sink integrated in the wall to dissipate the heat generated by one or more electronic components. The heat generated by the electronic components, such as a CPU, is transferred to the heat sink via a heat conduit. The heat is then dissipated by the heat sink by drawing cooler air from outside the tablet unit via the gaps between the plurality of fins of the heat sink.

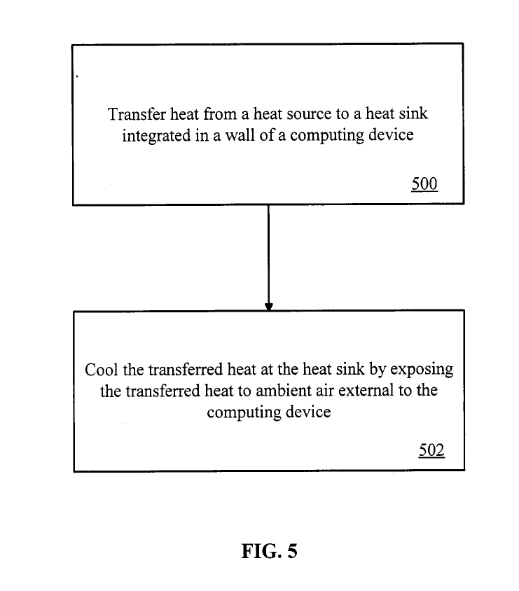

FIG. 5 is a flow diagram illustrating a method according to an embodiment of the invention. At 500, heat is transferred from a heat source to a heat sink integrated in a wall of a computing device. In one embodiment, the heat is transferred by a heat pipe from the heat source to the heat sink. At 502, the transferred heat is cooled at the heat sink by exposing the transferred heat to ambient air external to the computing device. In one embodiment, the transferred heat is cooled at the heat sink by exposing the heat to ambient air external to the computing device via gaps between a plurality of fins of the heat sink. In one embodiment, air is blown toward the heat sink by an air movement device, such as a fan.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A computing device comprising:
a heat sink integrated in a wall of the computing device; and
a heat conduit to transfer heat generated by a heat source to the heat sink.

2. The computing device of claim 1, wherein the heat sink includes a plurality of fins with gaps in between the fins to allow ambient air external to the computing device to flow into the computing device.

3. The computing device of claim 1, wherein the heat conduit is a heat pipe coupled to the heat source.

4. The computing device of claim 1, wherein the heat source is a central processing unit (CPU).

5. The computing device of claim 1, wherein the computing device is a mobile computing device.

6. The computing device of claim 1, wherein the computing device is a laptop.

7. The computing device of claim 1, wherein the computing device is a tablet personal computer (PC).

8. The computing device of claim 1, further comprising a cover placed over the heat sink.

9. The computing device of claim 8, wherein the cover has vents to allow air external to the computing device to pass through to the heat sink.

10. A method comprising:
transferring heat from a heat source to a heat sink integrated in a wall of a computing device; and
cooling the transferred heat at the heat sink by exposing the transferred heat to ambient air external to the computing device.

11. The method of claim 10, wherein transferring heat from the heat source to the heat sink comprises transferring heat to the heat sink via a heat pipe coupled to the heat source.

12. The method of claim 10, wherein cooling the transferred heat at the heat sink comprises cooling the transferred heat at the heat sink by exposing the transferred heat to ambient air external to the computing device via gaps between a plurality of fins of the heat sink.

13. The method of claim 10, wherein transferring heat from the heat source to the heat sink comprises transferring heat from a central processing unit (CPU) to the heat sink.

14. The method of claim 10, further comprising blowing air toward the heat sink by an air movement device.

15. The method of claim 14, wherein the air movement device is a fan.

16. The method of claim 10, wherein the computing device is mobile computing device.

17. The method of claim 10, wherein the computing device is a tablet personal computer (PC).

18. A computer system comprising:
a base; and
a tablet unit detachably coupled to the base, the tablet unit including:
a central processing unit (CPU);
a heat sink integrated with a wall of the tablet unit; and
a heat conduit coupled to the CPU to transfer heat from the CPU to the heat sink.

19. The system of claim 18, wherein the heat sink includes a plurality of fins with gaps in between the fins to allow ambient air external to the tablet unit to flow into the tablet unit.

20. The system of claim 18, wherein the heat conduit is a heat pipe coupled to the CPU.

21. The system of claim 18, wherein the tablet unit includes a screen for entering and displaying data;

22. The system of claim 18, further comprising an air movement device to blow air toward the heat sink.

23. The system of claim 22, wherein the air movement device is a fan.
